(19) United States
(12) Patent Application Publication
(10) Pub. No.: US 2023/0290692 A1
(43) Pub. Date: Sep. 14, 2023

(54) CHIP GRADING METHOD AND PACKAGING METHOD, AND CHIP GRADING SYSTEM AND PACKAGING SYSTEM

(71) Applicant: CHANGXIN MEMORY TECHNOLOGIES, INC., Hefei City (CN)

(72) Inventor: CHIA-SHENG LIN, Hefei (CN)

(73) Assignee: CHANGXIN MEMORY TECHNOLOGIES, INC., Hefei City (CN)

(21) Appl. No.: 17/871,820

(22) Filed: Jul. 22, 2022

Related U.S. Application Data
(63) Continuation of application No. PCT/CN2022/081977, filed on Mar. 21, 2022.

(30) Foreign Application Priority Data
Mar. 14, 2022 (CN) 202210247246.3

(51) Int. Cl. H01L 21/66; H01L 21/67; G06K 9/62

(52) U.S. Cl. CPC H01L 22/20; G06K 9/6218; G06K 9/6247; H01L 21/67271; H01L 21/67288

(57) ABSTRACT

A chip grading method includes: electrical performance test data of at least one wafer is acquired; chips on the wafer are grouped by using a clustering analysis algorithm according to the electrical performance test data of the wafer, so as to obtain a group to which each of the chips belongs, and a clustering model is established; for each group, a feature set of each group is extracted by using a Principal Component Analysis (PCA) algorithm, and a PCA model is established; the chips in each group are ranked according to scores of the chips in the group with respect to each of a preset number of features in the feature set, so as to obtain a level to which each of the chips belongs; and grading results of the chips are obtained according to both the group and the level to which each chip belongs.

### CROSS-REFERENCE TO RELATED APPLICATIONS

This application is a continuation of International Patent Application No. PCT/CN2022/081977, filed on Mar. 21, 2022, which claims priority to Chinese Patent Application No. 202210247246.3, filed on Mar. 14, 2022. The disclosures of these applications are hereby incorporated by reference in their entirety.

### BACKGROUND

Due to fine structures and complex manufacturing processes of chips, defects will inevitably appear in production processes. Therefore, during the production and manufacturing of the chips, manufacturers usually test the chips to ensure the quality of the chips and prevent defective products from mixing with good products into a next process.

In a related technical solution for packaging the chips, steps of chip testing, chip binning, and chip packaging are usually included. The chips are tested automatically through a test machine. The chips are simply divided into good products, inferior products, and defective products according to a test result, and the good products, the inferior products, and the defective products are respectively placed in different material trays according to a binning result. Reference is made to FIG. 1, which illustrates a schematic flowchart of packaging a chip in the related technical solution. As shown in FIG. 1, N chips classified into the same bin are randomly selected for performing Multiple Chip Package (MCP).

However, the binning is a rough selection method. The chips in the same bin may differ greatly in certain parameters. If these parameters dominate the performance of the chips, N chips randomly selected and classified in the same bin for packaging may lead to unstable quality of packaged products, which increases the risk of returning the products.

Therefore, the methods for classifying the chips and the methods for selecting the chips for packaging at present still need to be further improved.

### SUMMARY

The embodiments of the disclosure relate to the technical field of semiconductors, and in particular, to a chip grading method and packaging method, and a chip grading system and packaging system.

In view of the above, the embodiments of the disclosure provide a chip grading method and packaging method, and a chip grading system and packaging system.

To achieve the abovementioned objective, the technical solution of the disclosure is implemented as follows.

In a first aspect, the embodiments of the disclosure provide a chip grading method. The method may include the following operations. Electrical performance test data of at least one wafer is acquired. Chips on the wafer are grouped by using a clustering analysis algorithm according to the electrical performance test data of the wafer, so as to obtain a group to which each of the chips belongs, and a clustering model is established. For each group, a feature set of each group is extracted by using a Principal Component Analysis (PCA) algorithm, and a PCA model is established. The chips in each group are ranked according to scores of the chips in the group with respect to each of a preset number of features in the feature set, so as to obtain a level to which each of the chips belongs. Grading results of the chips are obtained according to both the group and the level to which each chip belongs.

In a second aspect, the embodiments of the disclosure provide a chip grading system. The system may include a memory storing processor-executable instructions, and a processor. The processor is configured to execute the stored processor-executable instructions to perform operations of: acquiring electrical performance test data of at least one wafer; grouping chips on the wafer by using a clustering analysis algorithm according to the electrical performance test data of the wafer, so as to obtain a group to which each of the chips belongs, and establishing a clustering model; for each group, extracting a feature set of each group by using a Principal Component Analysis (PCA) algorithm, and establishing a PCA model; ranking chips in each group according to scores of the chips in the group with respect to each of a preset number of features in the feature set, so as to obtain a level to which each of the chips belongs: and obtaining grading results of the chips according to both the group and the level to which each chip belongs.

In a third aspect, the embodiments of the disclosure further provide a non-transitory computer-readable storage medium having stored thereon computer-executable instructions that, when executed by a processor, cause the processor to perform operations of: acquiring electrical performance test data of at least one wafer; grouping chips on the wafer by using a clustering analysis algorithm according to the electrical performance test data of the wafer, so as to obtain a group to which each of the chips belongs, and establishing a clustering model; for each group, extracting a feature set of each group by using a Principal Component Analysis (PCA) algorithm, and establishing a PCA model; ranking chips in each group according to scores of the chips in the group with respect to each of a preset number of features in the feature set, so as to obtain a level to which each of the chips belongs; and obtaining grading results of the chips according to both the group and the level to which each chip belongs.

### BRIEF DESCRIPTION OF THE DRAWINGS

FIG. 1 illustrates a flowchart of packaging a chip in a related technical solution.

FIG. 2 illustrates an optional flowchart of a chip grading method provided by the embodiments of the disclosure.

FIG. 3 illustrates a flowchart of a chip grading method provided by a specific example in the embodiments of the disclosure.

FIG. 4A to FIG. 4H illustrate implementation flowcharts of various steps of a chip grading method provided by a specific example in the embodiments of the disclosure.

FIG. 5 illustrates a flowchart of grading chips on a wafer to be tested provided by the embodiments of the disclosure.

FIG. 6 illustrates a flowchart of establishing and applying a clustering analysis model and a PCA model provided by the embodiments the disclosure.

FIG. 7 illustrates a flowchart of executing a chip grading method with a distributed computing server provided by the embodiments of the disclosure.

FIG. 8 illustrates a flowchart of packaging a chip on chip provided by the embodiments of the disclosure.

FIG. 9 illustrates a flowchart of packaging a wafer on wafer provided by the embodiments of the disclosure.

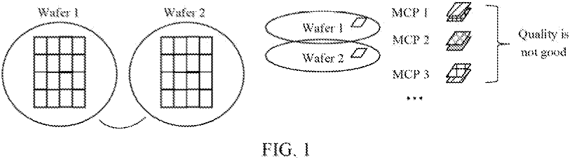

### DETAILED DESCRIPTION

Technical solutions in the implementation modes of the disclosure will be clearly and completely described below with reference to the implementation modes and the drawings in the disclosure. Apparently, the described implementation modes are merely part rather than all of the implementation modes of the disclosure. Based on the implementation modes of the disclosure, all other implementation modes obtained by those of ordinary skill in the art without creative efforts fall within the scope of protection of the disclosure.

In the following description, a large number of specific details are given in order to provide a more thorough understanding of the disclosure. However, it will be apparent to those skilled in the art that the disclosure may be implemented without one or more of these details. In other examples, in order to avoid confusion with the disclosure, some technical features known in the art are not described. That is, all the features of the actual embodiments are not described here, and the known functions and structures are not described in detail.

In the drawings, the dimensions of layers, areas, and elements and their relative dimensions may be exaggerated for clarity. Throughout, the same drawing signs represent the same elements.

It is to be understood that description that an element or layer is “above”, “adjacent to”, “connected to”, or “coupled to” another element or layer may refer to that the element or layer is directly above, adjacent to, connected to or coupled to the other element or layer, or there may be an intermediate element or layer. On the contrary, description that an element is “directly on”, “directly adjacent to”, “directly connected to” or “directly coupled to” another element or layer refers to that there is no intermediate element or layer. It is to be understood that, although various elements, components, areas, layers, and/or parts may be described with terms first, second, third, etc., these elements, components, areas, layers, and/or parts should not be limited to these terms. These terms are used only to distinguish one element, component, area, layer or part from another element, component, area, layer or part. Therefore, a first element, component, area, layer, or part discussed below may be represented as a second element, component, area, layer, or part without departing from the teaching of the disclosure. However, when the second element, component, area, layer, or part is discussed, it does not mean that the first element, component, area, layer, or part must exist in the disclosure.

Spatial relational terms such as “under”, “below”, “lower”, “beneath”, “above”, “upper” and the like may be used herein for ease of description to describe the relationship between one element or feature and other elements or features illustrated in the drawings. It should be understood that in addition to the orientations shown in the drawings, the spatial relationship term intention further includes different orientations of devices in use and operation. For example, if the devices in the drawings are overturned, then the elements or features described as “under” or “below” or “beneath” will be oriented to be “above” other elements or features. Therefore, exemplary terms “under” and “below” may include upper and lower orientations. The devices may be otherwise oriented (rotated 90 degrees or other orientations) and the spatial descriptors used herein are interpreted accordingly.

The terms used herein are intended only to describe specific embodiments and are not a limitation of the disclosure. As used herein, singular forms “a/an”, “one”, and “the” may also be intended to include the plural forms, unless otherwise specified types in the context. It is also to be understood that, when terms “composed of” and/or “including” are used in this specification, the presence of the features, integers, steps, operations, elements, and/or components may be determined, but the presence or addition of one or more other features, integers, steps, operations, elements, components, and/or groups is also possible. As used herein, terms “and/or” includes any and all combinations of the related listed items.

In order to thoroughly understand the disclosure, detailed steps and detailed structures will be proposed in the following description in order to explain the technical solution of the disclosure. Preferred embodiments of the disclosure are described in detail below. However, in addition to these detailed descriptions, the disclosure may have other implementation modes.

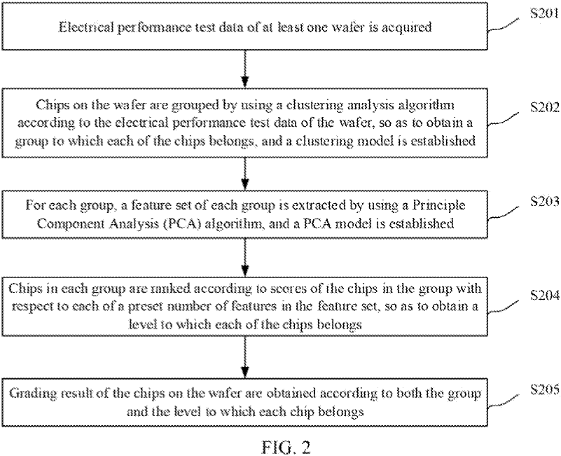

Reference is made to FIG. 2, which illustrates an optional flowchart of a chip grading method provided by the embodiments of the disclosure. As shown in FIG. 2, the embodiments of the disclosure provide a chip grading method. The method may include the following steps.

At S201, electrical performance test data of at least one wafer is acquired.

At S202, chips on the wafer are grouped by using a clustering analysis algorithm according to the electrical performance test data of the wafer, so as to obtain a group to which each of the chips belongs, and a clustering model is established.

At S203, for each group, a feature set of each group is extracted by using a PCA algorithm, and a PCA model is established.

At S204, the chips in each group are ranked according to scores of the chips in the group with respect to each of a preset number of features in the feature set, so as to obtain a level to which each of the chips belongs.

At S205, grading results of the chips are obtained according to both the group and the level to which each chip belongs.

In some embodiments, in S201, electrical performance test data of at least one wafer is acquired. The electrical performance test data includes Circuit Probe (CP) test data. The CP is between wafer manufacturing and chip packaging in the whole chip manufacturing process. After the wafer manufacturing is completed, thousands of dies, that is, unpackaged chips, are regularly distributed all over the wafer. Since scribing and packaging have not been performed, all pins of the chip are exposed, and these tiny pins need to be connected to a test handler through finer probes. On the whole wafer that is not scribed and packaged, the dies are connected to the test handler through the probes, so as to perform chip test, that is, the CP test. During CP test, unqualified chips are marked, and the marked unqualified chips are eliminated when a chip is cut into separate chips, and qualified chips are selected for packaging.

Here, main devices for the CP test mainly include three parts: a probe test handler, a probe tester, and a probe test card, all of which are tested by a test system using a test program. The probe handler is mainly responsible for corresponding precision contact between the probe of the probe test card and the pins on each chip on the wafer. The contact quality will directly affect the test results. A position control module of the test handler controls a wafer bearing table to move according to a working instruction, positions the wafer, and accurately conveys the wafer to a test position, so as to realize automatic test. The probe tester mainly realizing the tasks of electrical performance test, and the functions of downloading of a test program, applying voltage and current, and acquiring test data. During the test, the test system extracts a corresponding test program according to the category of the chip to be tested. The test program will control the probe tester to complete initial setting, send a test signal through the test system, start to test a chip, store and grade a test result, and gives a test result report. The probe test card is a connection between the test system and the wafer, and consists of a circuit board and a probe. The circuit board is connected to the probe tester, and the probe is connected to a chip on the wafer, so as to directly collect an input signal of the wafer or check an output value.

In some embodiments, the CP test data includes Direct Current (DC) test data, Alert Current (AC) test data, and function test data. The test program tests the chip by transforming different voltages, currents, and timings, and then performs the work of debugging and characterizing. The DC test includes a short circuit test, an open circuit test, a maximum current test, etc. The AC test mainly aims at a timing test, including a transmission delay test, establishment and retention time test, functional speed test, etc. The function test includes read recycle, write cycle, fast page mode check, enhanced data-out mode check, etc.

In some embodiments, at S202, the clustering analysis algorithm includes a partition clustering algorithm, a hierarchical clustering algorithm, a fuzzy clustering algorithm and a density-based clustering algorithm. Here, clustering analysis refers to an analysis process of grouping a set of physical or abstract objects into multiple categories composed of similar objects. In a specific embodiment, the clustering analysis algorithm includes a k-means clustering algorithm. Here, the k-means clustering algorithm is an iterative solution method, which divides data into K groups in advance, randomly selects K objects as an initial clustering center, then calculates the distance between each object and each seed clustering center, and assigns each object to a clustering center closest thereto. The clustering centers and the objects assigned to them represent a cluster. Each time a sample is assigned, the cluster center of the cluster will be recalculated according to the existing objects in the cluster. The process will be continuously repeated until a termination condition is satisfied. The termination condition may be that no (or a minimum number of) object are reassigned to different clusters, no (or a minimum number of) cluster centers change again, or the sum of squares of errors is locally minimum.

In the embodiments of the disclosure, the clustering analysis algorithm being the K-means clustering algorithm is taken as an example to illustrate. The chips on the wafer are grouped by using the K-means clustering algorithm, so as to obtain a group to which each of the chips belongs, and a clustering model is established. Of course, the clustering analysis algorithm in the embodiments of the disclosure is not limited to the K-means clustering algorithm. Other clustering analysis algorithms may also be applied to the chip grading method provided by the embodiments of the disclosure for grouping the chips on the wafer.

In some embodiments, the operation that all features of the group are extracted by using the PCA algorithm to form the feature set and the PCA model is established includes the following operations.

For each group, all features of the group are extracted by using the PCA algorithm to form the feature set, and the PCA model is established.

The method may further include: the preset number of features are selected from the feature set. A total contribution rate of the preset number of features conforms to a preset contribution rate.

Here, at S203, for each group, a feature set of each group is extracted by using a PCA algorithm, and a PCA model is established. The PCA refers to that a group of variables that may have correlation into a group of linearly uncorrelated variables through orthogonal transformation. This group of transformed variables is called principal components. In the embodiments of the disclosure, the electrical performance test of the wafer includes a plurality of test items, and there is high correlation between the parameters of a plurality of test items. This correlation can be explained that the parameters of these test items reflect the information of the wafer overlaps to some extent. The PCA is to delete redundant repeated variables (closely related variables) for all variables proposed originally, and establish as few new variables as possible for all the originally proposed variables, so that these new variables are irrelevant, and these new variables keep the original information as much as possible in reflecting the information of an object. That is to say, the number of variables can be reduced and more information can be retained as much as possible through the PCA. In the embodiments of the disclosure, the feature set composed of all features of the each group is called the abovementioned variables.

In some embodiments of the disclosure, a number of the features in the feature set of each group is less than a number of test items of the electrical performance test data.

Here, assuming that the number of test items of the electrical performance test data is n, after the electrical performance test data is subjected to group analysis, the number of the test items of the electrical performance test data remains unchanged, and then each group is subjected to the PCA, and all features of each group are extracted to form a feature set. The feature set includes r features, where r is less than n.

In some embodiments, for each group, all features of the group are extracted to from the feature set. The contribution rate corresponding to each feature in the feature set is calculated, and the influence degree of each feature on the wafer is output in a descending order of the contribution rates. A preset number of features are selected from the feature set. A total contribution rate of the preset number of features confirms to a preset contribution rate.

Here, the preset number of features may reflect all information of each group. For example, a feature with a cumulative contribution rate of 80% may be selected to reflect all the information of each group.

In some embodiments, the feature sets of different groups have different preset numbers of the features.

Here, for each group, all features included in the feature set are sorted in a descending order of the construction rates, and the first M features are selected to represent the information of the group, that is, the cumulative contribution rate of the first M features confirms to the preset contribution rate. Different preset numbers of features may be selected from the feature sets in different groups to represent the information of respective groups. For example, the first three features may be selected from the feature set of one group, and a total contribution rate of the first three features confirms to the preset contribution rate: and the first five features may be selected from the feature set of another group, and the total contribution rate of the first five features confirms to the preset contribution rate. Of course, the preset numbers of the features selected from the feature sets of different groups are not limited to the abovementioned examples.

In other embodiments, the feature sets of different groups may have a same preset number of the features.

Here, at S204, the chips in each group are ranked according to scores of the chips in the group with respect to each of a preset number of features in the feature set, so as to obtain a level to which each of the chips belongs.

In some embodiments, the operation that the chips in each group are ranked according to scores of the chips in the group with respect to each of a preset number of features in the feature set includes the following operations.

A level interval of each of the preset number of features in the feature set of each group is obtained according to the scores of the chips in the group with respect to each of the preset number of features in the feature set.

The chips in each group are ranked according to the level interval of each of the preset number of features in the feature set and the scores of the chips with respect to each of the preset number of features in the feature set.

In some embodiments, the operation that the chips in each group are ranked according to the level interval of each of the preset number of features in the feature set and the scores of the chips with respect to each of the preset number of features in the feature set may include the following operations.

The level interval of each of the preset number of features in the feature set to which the chips belong is determined according to the level interval of each of the preset number of features in the feature set and the scores of the chips with respect to each of the preset number of features in the feature set.

A sub-level of each of the preset number of features in the feature set to which the chips belong is determined according to the level interval of each of the preset number of features in the feature set to which the chips belong.

The chips in each group are ranked according to the sub-level of each of the preset number of features in the feature set to which the chips belong.

In some embodiments, the operation that the chips in each group are ranked according to the sub-level of each of the preset number of features in the feature set to which the chips belong may include the following operations.

For each of the chips in each group, a total score of each of the chips with respect to each of the preset number of features in the feature set is calculated according to a weight of the sub-level of each of the preset number of features in the feature set to which the chips belong.

The level to which each chip belongs is determined according to the total score.

Here, for each group, all features included in the feature set are sorted in a descending order of the construction rates, and the first M features are selected to represent the information of the group. For each group, the score of the chip with respect to each of the preset number of features of the group is calculated to obtain a level interval of each of the preset number of features of the group, so that a sub-level of the chip with respect to each of the preset number of features of the group may be determined. Further, a total score of the chip with respect to each of the preset number of features is calculated according to the weight of the sub-level of each of the preset number of features; and the level to which each chip belongs is determined according to the total score. For example, for a certain group, the first three features are selected to represent the information of the group; the scores of all chips in the group on three features of the groups are calculated; it is obtained, according to the scores of all chips in the group respectively in the three features of the group, that each of the three features of the group includes three level intervals, that is, each of the three features includes three sub-levels; the sub-levels of all chips in the group on the three features are determined, and the total scores of the chips on the three features are obtained by calculating in combination with the weights of the sub-levels; and the levels of the chips on the three features are determined according to the total score.

In some embodiments, the operation that the chips in each group are ranked according to the sub-levels of each of the features in the feature set to which the chips belong includes the following operations.

The number of the features at each of the sub-levels to which the chips belong is determined according to the sub-levels of each of the preset number of features in the feature set to which the chips belong.

The level to which each chip belongs is determined according to the number of the features at each of the sub-levels to which the chips belong.

Here, for a certain group, the first three features are still selected to represent the information of the group: the scores of all chips in the group with respect to the three features of the group are calculated: it is obtained, according to the scores of all chips in the group respectively with respect to the three features of the group, that each of the three features of the group includes three level intervals, that is, each of the three features includes three sub-levels; and the number of the features at each of the sub-levels of all chips in the group is determined, for example, if the sub-levels of a certain chip with respect to three features of the group are all sub-level 2, then it is obtained that the level of the chip is also level 2.

Here, at S205, grading results of the chips are obtained according to both the group and the level to which each chip belongs.

According to the chip grading method provided by the embodiments of the disclosure, chips are divided into different groups by using a clustering analysis algorithm, the chips in each group are divided into levels by using a PCA algorithm, and the chips are graded according to both the group and the level to which each chip belongs, so as to ensure that the performance of the chips being to the same group and level is similar, thereby facilitating subsequent selection performance of chips with similar performance for packaging. Here, the chips are graded in consideration of the group and the level to which each chip belongs at the same time, so that the chips belonging to the same group and level are closer in performance.

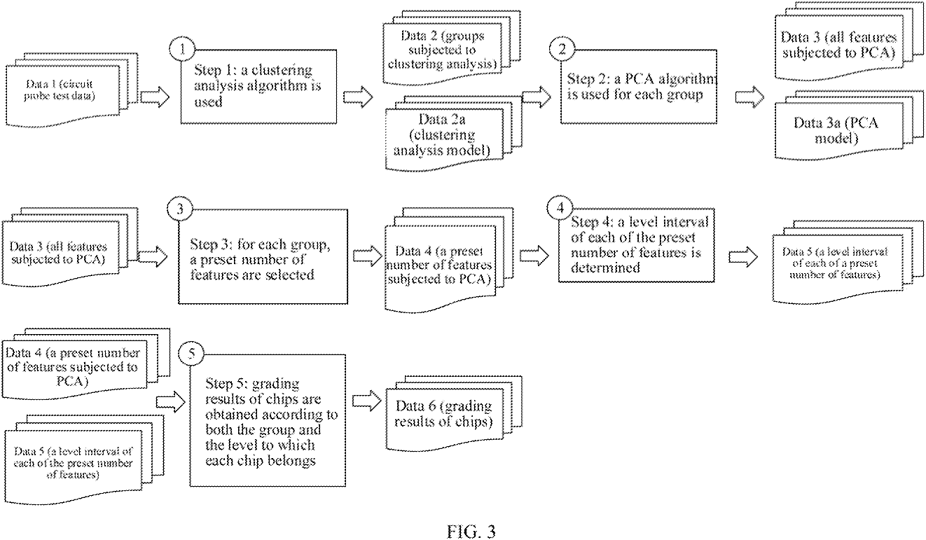

Reference is made to FIG. 3, which illustrates a flowchart of a chip grading method provided by a specific example in the embodiments of the disclosure. As shown in FIG. 3, data 1, that is, circuit probe test data of at least one wafer, is acquired; the data 1 is analyzed by using a clustering analysis algorithm, so as to obtain data 2 and data 2a, that is, a group subjected to clustering analysis and a clustering model; data 3 and data 3a, that is all features subjected to the PCA and a PCA model, are obtained by using the PCA algorithm on each group: data 3 is analyzed, and a preset number of features are selected for each group, so as to obtain data 4, that is, a preset number of features subjected to the PCA; data 4 is analyzed, and a level interval of each of a preset number of features is determined, so as to obtain data 5, that is, the level interval of each of the preset number of features; and analysis is performed in combination with data 4 and data 5, and data 6 is obtained according to both the group and level to which each chip belongs, that is, grading results of the chips are obtained.

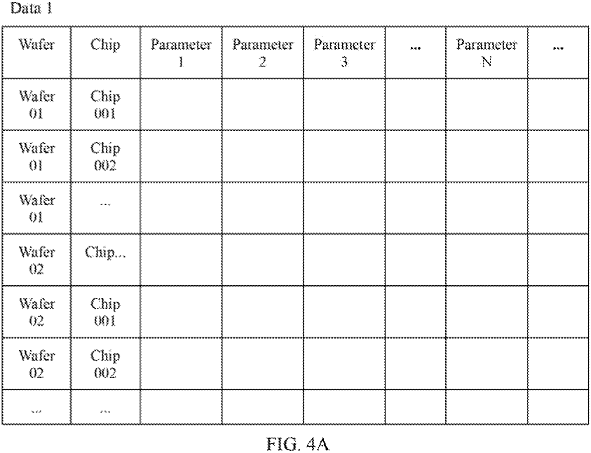

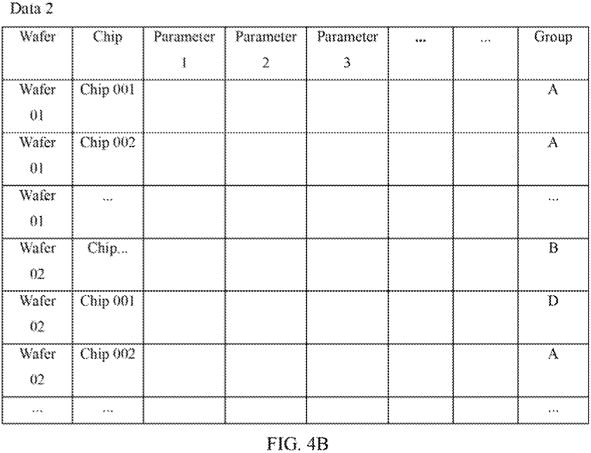

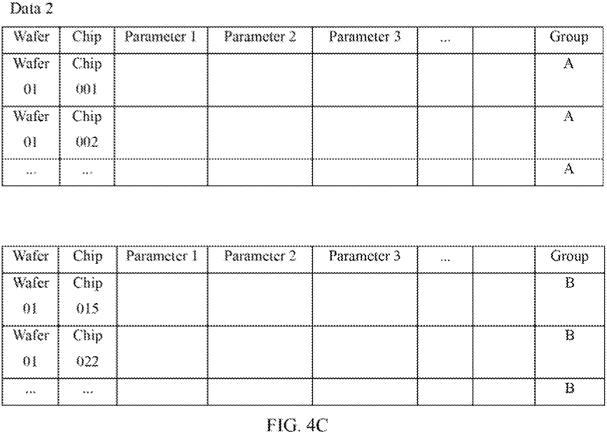

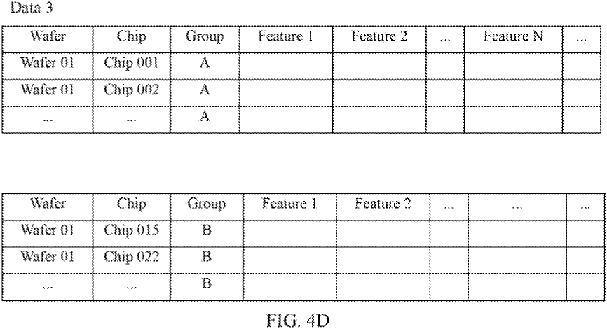

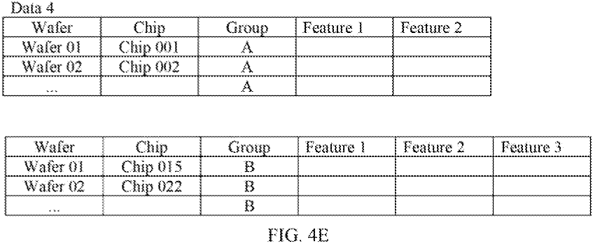

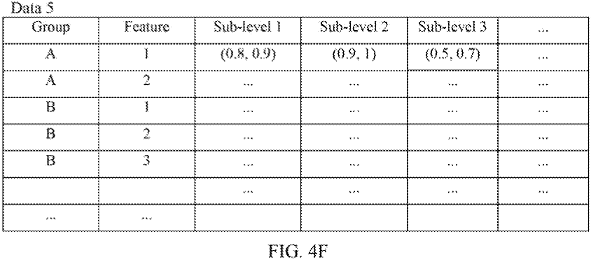

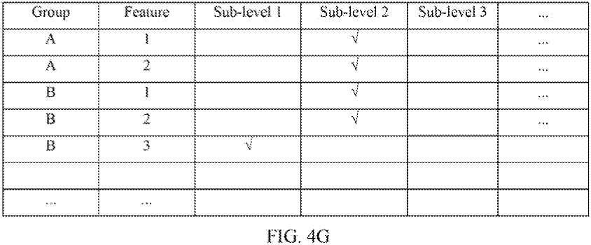

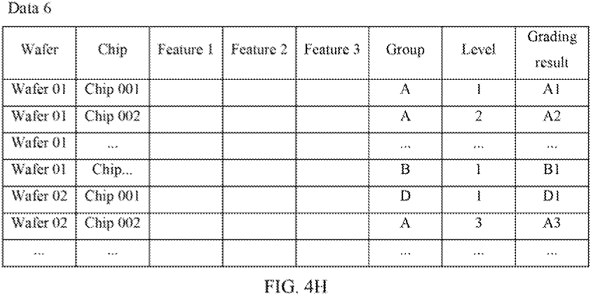

Reference is made to FIG. 4A to FIG. 4H, which illustrate implementation flowcharts of various steps of a chip grading method provided by a specific example in the embodiments of the disclosure. The chip grading method provided by the embodiments of the disclosure will be described below in combination with FIG. 4A to FIG. 4H.

As shown in FIG. 4A, data 1 include circuit probe test data of at least one wafer. The test data includes a plurality of test items, that is, the test data includes a plurality of test parameters. Here, usually, one wafer includes more than 20000 chips according to different sizes and different numbers of the chips on the wafer.

As shown in FIG. 4B, data 2 includes a group subjected to clustering analysis. Chips are subjected to K-means clustering algorithm according to the circuit probe test data, so as to obtain K groups. FIG. 4B illustrates chip 001 and chip 002 on wafer 01, chip 002 on wafer 02 belongs to group A, and chip 001 on wafer 02 belongs to group D.

As shown in FIG. 4C, the chips belonging to the same group are divided together. Both chip 001 and chip 002 on wafer 01 shown in FIG. 4C belong to group A, and both chip 015 and chip 022 on wafer 01 belong to group B.

As shown in FIG. 4D, data 3 includes all features subjected to PCA. FIG. 4D illustrates that the PCA is performed on group A and group B, and all features of group A and group B are extracted to from respective feature sets.

As shown in FIG. 4E, data 4 includes a preset number of features subjected to the PCA. For group A, feature 1 and feature 2 are selected as the preset number of features, and the cumulative contribution rate of feature 1 and feature 2 conforms to a preset contribution rate. For group B, feature 1, feature 2, and feature 3 are selected as the preset number of features, and the cumulative contribution rate of feature 1, feature 2, and feature 3 conforms to a preset contribution rate.

As shown in FIG. 4F, data 5 includes level intervals of each of a preset number of features. For the chips in group A, the level intervals of the sub-levels of the chips with respect to feature 1 and feature 2 are obtained according to the scores of the chips with respect to feature 1 and feature 2, and the sub-levels of the chips respectively with respect to feature 1 and feature 2 are determined. For the chips in group B, the level intervals of the sub-levels of the chips with respect to feature 1, feature 2, and feature 3 are obtained according to the scores of the chips with respect to feature 1, feature 2, and feature 3, and the sub-levels of the chips respectively with respect to feature 1, feature 2, and feature 3 are determined.

As shown in FIG. 4G, if a certain chip in group A is at sub-level 2 with respect to feature 1 and also at sub-level 2 with respect to feature 2, then there are two features of the chip at sub-level 2, and it is obtained that the chip belongs to level 2.

As shown in FIG. 4G, if a certain chip in group B is at sub-level 2 with respect to feature 1, at sub-level 2 with respect to feature 2, and at sub-level 1 with respect to feature 3, then there is one feature of the chip at sub-level 1 and two features at sub-level 2, and it is obtained that the chip belongs to level 2.

Still referring to FIG. 4G, if a certain chip in group B is at sub-level 2 with respect to feature 1, at sub-level 2 with respect to feature 2, and at sub-level 1 with respect to feature 3, assuming that the weight of sub-level 1 is a, the weight of sub-level 2 is b, and the weight of sub-level 1 is c, a+b+c=100%, then the level of the chip can be obtained according to the sub-levels of the chip with respect to each feature and the weights of the sub-levels.

As shown in FIG. 4H, data 6 includes a grading result of the chip. If chip 001 on wafer 01 as shown in FIG. 4H belongs to group A and level 1, then it is obtained that the grading result of the chip is A1, according to group A and level 1 to which each chip belongs.

In some embodiments, the operation that the sub-level interval of each of the preset number of features in the feature set to which the chips belong is determined according to the level interval of each of the preset number of features in the feature set to which the chips belong includes: the level interval of each of the preset number of features in the feature set of each group is set, so that the levels of the sub-levels of the preset number of features in the feature set to which the chips belong are consistent with each other.

Here, still referring to FIG. 4F and FIG. 4G, when the sub-level interval on a certain feature in a certain group is divided, the sub-levels of the chips with respect to the preset number of features are made the same as much as possible. For example, a certain chip in group A is at sub-level 2 with respect to both feature 1 and feature 2.

In some embodiments, the method includes the following operations.

Electrical performance test data of at least one wafer to be tested is provided.

The electrical performance test data of the wafer to be tested is input into the clustering model, so as to obtain a group to which each of the chips on the wafer to be tested belongs.

The data of each group is input into the PCA model to obtain a feature set of each group.

The level to which each chip belongs is obtained according to the scores of the chips in the group with respect to each of a preset number of features in the feature set.

Grading results of the chips are obtained according to both the group and the level to which each chip belongs.

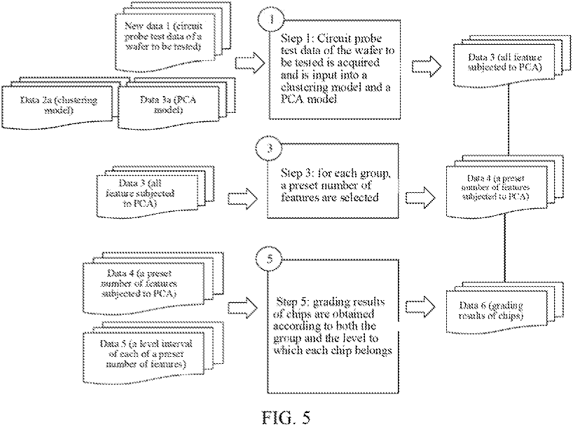

Reference is made to FIG. 5, which illustrates a flowchart of grading chips on a wafer to be tested provided by the embodiments of the disclosure. As shown in FIG. 5, new data 1, that is the circuit probe test data of the wafer to be tested, is input into the clustering model to obtain a group to which each chip on the wafer to be tested belongs; the data of each group is input into a PCA model to obtain data 3, that is a feature set formed by all features of each group; data 3 is analyzed, and for each group, a preset number of features are selected as data 4, that is, the preset number of features subjected to the PCA; data 4 is analyzed to determine a level interval of each of the preset number of features, so as to obtain data 5, that is, the level interval of each of the preset number of features; and analysis is performed in combination with data 4 and data 5, and data 6 is obtained according to both the group and the level to which each chip belongs, that is, a grading result of the chip. Thus, the chips on the wafer to be tested are graded by only inputting the circuit probe test data of the wafer to be tested into the established clustering model and PCA model.

According to the chip grading method provided by the embodiments of the disclosure, a clustering analysis model and a PCA model are also established at the same time in a process of grading the chips for the first time, and the groups and the levels to which the chips on the wafer to be tested belong can be obtained by only inputting electrical performance test data of the wafer to be tested into the established clustering analysis model and PCA model when the chips on the wafer to be tested are graded subsequently. Thus, the chip grading method can be simplified, the chip grading time can be shortened, and the chip grading efficiency can be improved.

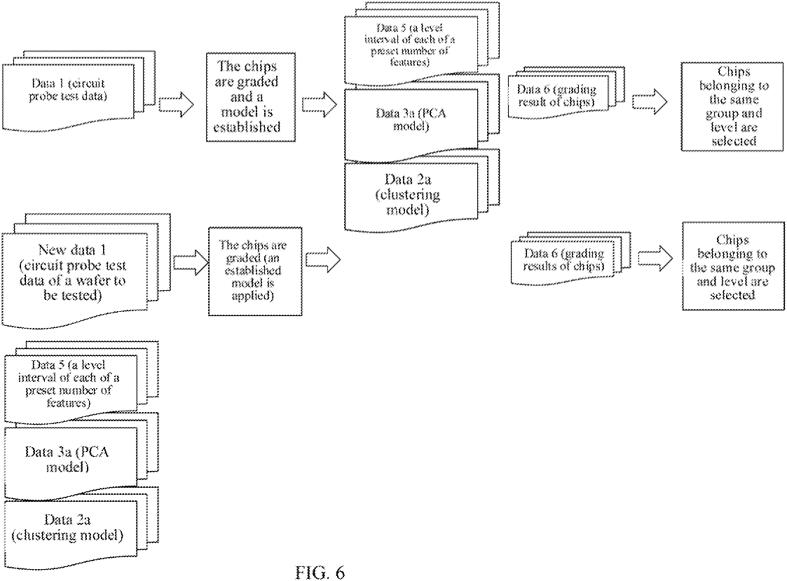

Reference is made to FIG. 6, which illustrates a flowchart of establishing and applying a clustering analysis model and a PCA model provided by the embodiments the disclosure. As shown in FIG. 6, when the chips are graded for the first tim, the clustering analysis model and the PCA model are also established when the group and the level to which each chip belongs are determined. Thus, the chips on the wafer to be tested are graded subsequently, and the grading results of the chips on the wafer to be tested can be obtained by only inputting the circuit probe test data of the wafer to be tested into the established models.

In some embodiments, the steps of grouping the chips on the wafer, extracting the feature set of each group, and ranking the chips in each group are executed by using a distributed computing server.

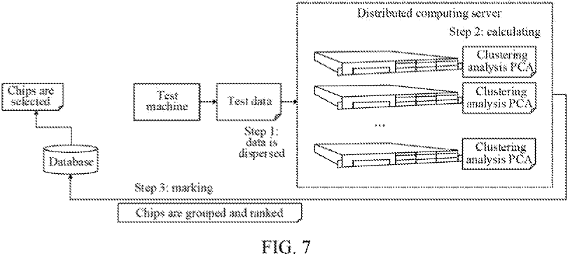

Reference is made to FIG. 7, which illustrates a flowchart of executing a chip grading method with a distributed computing server provided by the embodiments of the disclosure. In FIG. 7, at step 1, the test data of all chips on the wafer are tested by using a test machine, and the abovementioned test data is sent to the distributed computing server. At step 2, a clustering analysis algorithm and a PCA algorithm are set for each server, and the test data is analyzed by using the server. At step 3, grading results of all chips on the wafer are obtained, and a database is established.

Here, the greater the number of distributed servers, the more they can serve the test data from different test machines at the same time, which improves the efficiency of grading the chips.

In the embodiments of the disclosure, no limits are made to a distributed computing architecture, as long as the test data can be distributed to each server for computing.

In a preferred embodiment of the disclosure, memory type decentralized architecture may be used for performing real-time computing to accelerate the speed of grading the chips.

In some preferred embodiments, the steps of grouping the chips on the wafer, extracting the feature set of each group and ranking the chips in each group are performed by using a distributed computing server with a graphic processor unit.

In the embodiments of the disclosure, product requirements of each customer may be recorded in the database, the performance of the group and the level to which each chip belongs is directly connected with the requirements of the customer, and a package chip product that meet the requirements of the customer is provided for a specific customer, so as to achieve a high degree of automation.

The embodiments of the disclosure provide a chip packaging method. The method includes the following operations.

The grading results of the chips are obtained according to the chip grading method described in the abovementioned technical solution.

According to the grading results of the chips, at least two chips belonging to a same group and a same level are selected for performing package. The package is, for example, MCP.

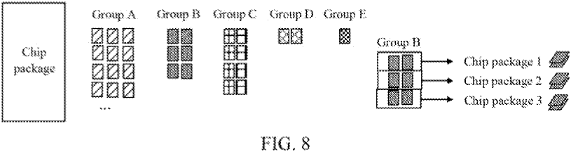

Reference is made to FIG. 8, which illustrates a flowchart of packaging a chip on chip provided by the embodiments of the disclosure. As shown in FIG. 8, at least two chips belonging to the same group and level are selected for performing package according to the grading results of chips obtained by the abovementioned chip grading method. Thus, it can ensure that the performance of each chip in the package chip is close and the overall quality of the package chip is more stable. In addition, both the group and the level to which each chip in the package chip belongs are the same. The advantages and disadvantages of the chip in performance can be understood from the group and the level to which each chip belongs, which is more beneficial for customers to select according to requirements.

In the embodiments of the disclosure, the chip with good performance is packaged, which facilitates the improvement of the quality of the package product, and is beneficial for manufacturers to price the package chip with higher quality. The chips with average performance are packaged, and the manufacturers can consider a low price, so as not to be unable to ship. Further, the package chips with close performance may be gathered before shipping, which is beneficial for the manufacturers to master the performance parameters of shipped products.

The embodiments of the disclosure provide a chip packaging method. The method includes the following operations.

The grading results of the chips are obtained according to the chip grading method described in the abovementioned technical solution.

A group distribution and a level distribution of the chips on each wafer are obtained according to the grading results of the chips.

At least two wafers are selected for packaging, where the chips on each of the at least two wafers have the group distribution and the level distribution satisfy a preset condition. The package is, for example, MCP.

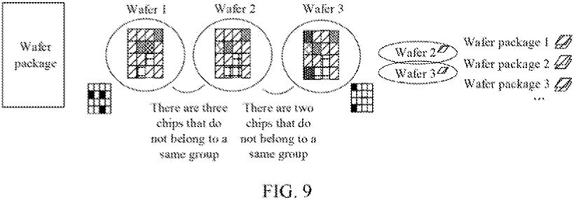

Reference is made to FIG. 9, which illustrates a flowchart of packaging a wafer on wafer provided by the embodiments of the disclosure. As shown in FIG. 9, the grading results of chips are obtained according to the abovementioned chip grading method, and the group distribution and the level distribution on each wafer, that is, the group and the level to which the chips at different positions of each wafer belong, are obtained according the abovementioned grading results of chips. There are three chips that do not belong to the same group in total between wafer 1 and wafer 2, and there are two chips that do not belong to the same group in total between wafer 2 and wafer 3, then the overall quality of package wafer products can be improved by packaging wafer 2 and wafer 3. If the group distributions of wafer 1, wafer 2, and wafer 3 are the same, then the level distributions of wafer 1, wafer 2, and wafer 3 are further compared, and the two wafers with closer level distributions are selected for performing package, so as to improve the overall quality of the package wafer products.

The embodiments of the disclosure further provide a chip grading system. The system includes a data acquisition module, a first algorithm module, a second algorithm module, a data processing module, and a data analysis module.

The data acquisition module is configured to acquire electrical performance test data of at least one wafer.

The first algorithm module is configured to: group chips on the wafer by using a clustering analysis algorithm according to the electrical performance test data of the wafer, so as to obtain a group to which each of the chips belongs; and establish a clustering model.

The second algorithm module is configured to: for each group, extract a feature set of each group by using a PCA algorithm, and establish a PCA model.

The data processing module is configured to rank the chips in each group according to scores of the chips in the group with respect to each of a preset number of features in the feature set, so as to obtain a level to which each of the chips belongs.

The data analysis module is configured to obtain grading results of the chips according to both the group and the level to which each chip belongs.

In some embodiments, the second algorithm module is specifically configured to: for each group, extract all features of the group by using the PCA algorithm to form the feature set, and establish the PCA model.

The data processing module is specifically configured to select the preset number of features from the feature set. The total contribution rate of the preset number of features conforms to a preset contribution rate.

In some embodiments, the data processing module is specifically configured to: obtain a level interval of each of the preset number of features in the feature set of each group according to the scores of the chips in the group with respect to each of the preset number of features in the feature set; and rank the chips in each group according to the level interval of each of the preset number of features in the feature set and the scores of the chips with respect to each of the preset number of features in the feature set.

In some embodiments, the data processing module is specifically configured to: determine the level interval of each of the preset number of features in the feature set to which the chips belong according to the level interval of each of the preset number of features in the feature set and the scores of the chips with respect to each of the preset number of features in the feature set; determine a sub-level of each of the preset number of features in the feature set to which the chips belong according to the level interval of each of the preset number of features in the feature set to which the chips belong; and rank the chips in each group according to the sub-level of each of the preset number of features in the feature set to which the chips belong.

In some embodiments, the first algorithm module is further configured to obtain the group to which each of the chips on the wafer to be tested belongs based on the clustering model.

The second algorithm module is further configured to obtain the feature set of each group based on the principal component analysis model.

The embodiments of the disclosure further provide a chip packaging system. The system includes: a chip packaging module and the chip grading system described in the abovementioned technical solution.

The chip packaging module is configured to select, according to the grading results of the chips, at least two chips belonging to a same group and a same level for performing package. The package is, for example, MCP.

The embodiments of the disclosure further provide a chip packaging system. The system includes: a wafer packaging module and the chip grading system described in the abovementioned technical solution.

The wafer packaging module is configured to obtain a group distribution and a level distribution of the chips on each wafer according to the grading results of the chips.

The wafer packaging module is further configured to select at least two wafers for packaging, where the chips on each of the at least two wafers have the group distribution and the level distribution satisfy a preset condition. The package is, for example, MCP.

The embodiments of the disclosure further provide an electronic device, including a memory, a processor, and a computer program stored on the memory. Steps of the method described in the abovementioned technical solution are implemented when a computer program is executed by the processor.

The embodiments of the disclosure further provide a computer-readable storage medium, which may store a computer program thereon. Steps described in the abovementioned method are implemented when the computer program is executed by a processor.

The embodiments of the disclosure provide a chip grading method and packaging method, and a chip grading system and packaging system. The grading method includes: electrical performance test data of at least one wafer is acquired; chips on the wafer are grouped by using a clustering analysis algorithm according to the electrical performance test data of the wafer, so as to obtain a group to which each of the chips belongs, and a clustering model is established: for each group, a feature set of each group is extracted by using a PCA algorithm, and a PCA model is established; the chips in each group are ranked according to scores of the chips in the group with respect to each of a preset number of features in the feature set, so as to obtain a level to which each of the chips belongs; and grading results of the chips are obtained according to both the group and the level to which each chip belongs. According to the chip grading method provided by the embodiments of the disclosure, chips are divided into different groups by using a clustering analysis algorithm, the chips in each group are divided into levels by using a PCA algorithm, and the chips are graded according to both the group and the chip to which each chip belongs, so as to ensure that the performance of the chips being to the same group and level is similar, thereby facilitating subsequent selection of chips for packaging. In addition, according to the chip grading method provided by the embodiments of the disclosure, a clustering analysis model and a PCA model are also established, and the groups and the levels to which the chips on the wafer to be tested belong can be obtained by inputting electrical performance test data of the wafer to be tested into the established clustering analysis model and PCA model.

It should be understood that “one embodiment” or “an embodiment” mentioned throughout the specification means that specified features, structures, or characteristics related to the embodiment are included in at least one embodiment of the disclosure. Therefore, “in one embodiment” or “in an embodiment” appearing throughout the specification does not necessarily refer to a same embodiment. In addition, these specified features, structures, or characteristics may be combined in one or more embodiments in any appropriate manner. It is to be understood that, in each embodiment of the disclosure, a magnitude of a sequence number of each process does not mean an execution sequence and the execution sequence of each process should be determined by its function and an internal logic and should not form any limit to an implementation process of the embodiments of the disclosure. The sequence numbers of the embodiments of the disclosure are adopted not to represent superiority-inferiority of the embodiments but only for description.

The above description is only preferred implementation modes of the disclosure, and thus does not limit the patent scope of the disclosure. Equivalent structure transformations made by the specification and the contents of the accompanying drawings of the disclosure under the inventive concept of the disclosure, or direct/indirect application in other related technical fields are all included in the scope of protection of the patent of the disclosure.

According to the chip grading method provided by the embodiments of the disclosure, chips are divided into different groups by using a clustering analysis algorithm, the chips in each group are divided into levels by using a PCA algorithm, and the chips are graded according to both the group and the chip to which each chip belongs, so as to ensure that the performance of the chips being to the same group and level is similar, thereby facilitating subsequent selection of chips for packaging. In addition, according to the chip grading method provided by the embodiments of the disclosure, a clustering analysis model and a PCA model are also established, and the groups and the levels to which the chips on the wafer to be tested belong can be obtained by inputting electrical performance test data of the wafer to be tested into the established clustering analysis model and PCA model, which facilitates subsequent selection of chips for packaging.

What is claimed is:

1. A chip grading method, comprising:
acquiring electrical performance test data of at least one wafer,
grouping chips on the wafer by using a clustering analysis algorithm according to the electrical performance test data of the wafer, so as to obtain a group to which each of the chips belongs, and establishing a clustering model;
for each group, extracting a feature set of each group by using a Principal Component Analysis (PCA) algorithm, and establishing a PCA model;
ranking chips in each group according to scores of the chips in the group with respect to each of a preset number of features in the feature set, so as to obtain a level to which each of the chips belongs; and
obtaining grading results of the chips according to both the group and the level to which each chip belongs.

2. The chip grading method of claim 1, wherein extracting the feature set of each group by using the PCA algorithm and establishing the PCA model comprises:
for each group, extracting all features of the group by using the PCA algorithm to form the feature set, and establishing the PCA model; and
the method further comprises: selecting the preset number of features from the feature set, wherein a total contribution rate of the preset number of features conforms to a preset contribution rate.

3. The chip grading method of claim 2, wherein ranking the chips in each group according to the scores of the chips in the group with respect to each of the preset number of features in the feature set comprises:
obtaining a level interval of each of the preset number of features in the feature set of each group according to the scores of the chips in the group with respect to each of the preset number of features in the feature set; and
ranking the chips in each group according to the level interval of each of the preset number of features in the feature set and the scores of the chips with respect to each of the preset number of features in the feature set.

4. The chip grading method of claim 3,wherein the ranking the chips in each group according to the level interval of each of the preset number of features in the feature set and the scores of the chips with respect to each of the preset number of features in the feature set comprises:
determining the level interval of each of the preset number of features in the feature set to which the chips belong according to the level interval of each of the preset number of features in the feature set and the scores of the chips with respect to each of the preset number of features in the feature set;
determining a sub-level of each of the preset number of features in the feature set to which the chips belong according to the level interval of each of the preset number of features in the feature set to which the chips belong; and
ranking the chips in each group according to the sub-level of each of the preset number of features in the feature set to which the chips belong.

5. The chip grading method of claim 4, wherein the ranking the chips in each group according to the sub-level of each of the preset number of features in the feature set to which the chips belong comprises:
for each of the chips in each group, calculating a total score of each of the chips with respect to each of the preset number of features in the feature set according to a weight of the sub-level of each of the preset number of features in the feature set to which the chips belong; and
determining the level to which each chip belongs according to the total score.

6. The chip grading method of claim 4, wherein determining the sub-level of each of the preset number of features in the feature set to which the chips belong according to the level interval of each of the preset number of features in the feature set to which the chips belong comprises:
setting the level interval of each of the preset number of features in the feature set of each group, so that the sub-levels of the preset number of the features in the feature set to which the chips belong are consistent with each other.

7. The chip grading method of claim 1, wherein the feature sets of different groups have different preset numbers of the features.

8. The chip grading method of claim 1, wherein the steps of grouping the chips on the wafer, extracting the feature set of each group and ranking the chips in each group are performed by using a distributed computing server with a graphic processor unit.

9. The chip grading method of claim 1, comprising:
providing electrical performance test data of at least one wafer to be tested;
inputting the electrical performance test data of the wafer to be tested into the clustering model, so as to obtain a group to which each of the chips on the wafer to be tested belongs;
inputting the data of each group into the PCA model to obtain a feature set of each group;
obtaining the level to which each chip belongs according to the scores of the chips in the group with respect to each of the preset number of features in the feature set, and
obtaining the grading results of the chips according to both the group and the level to which each chip belongs.

10. A chip packaging method, comprising:
obtaining the grading results of the chips according to the chip grading method of claim 1 ; and
selecting, according to the grading results of the chips, at least two chips belonging to a same group and a same level for packaging.

11. A chip packaging method, comprising:
obtaining the grading results of the chips according to the chip grading method of claim 1;
obtaining a group distribution and a level distribution of the chips on each wafer according to the grading results of the chips; and
selecting at least two wafers for packaging, wherein the chips on each of the at least two wafers have the group distribution and the level distribution satisfy a preset condition.

12. A chip grading system, comprising:
a memory storing processor-executable instructions; and
a processor configured to execute the stored processor-executable instructions to perform operations of:
acquiring electrical performance test data of at least one wafer,
grouping chips on the wafer by using a clustering analysis algorithm according to the electrical performance test data of the wafer, so as to obtain a group to which each of the chips belongs, and establishing a clustering model;
for each group, extracting a feature set of each group by using a Principal Component Analysis (PCA) algorithm, and establishing a PCA model;
ranking chips in each group according to scores of the chips in the group with respect to each of a preset number of features in the feature set, so as to obtain a level to which each of the chips belongs; and
obtaining grading results of the chips according to both the group and the level to which each chip belongs.

13. The chip grading system of claim 12, wherein extracting the feature set of each group by using the PCA algorithm and establishing the PCA model comprises:
for each group, extracting all features of the group by using the PCA algorithm to form the feature set, and establish the PCA model: and
the processor is configured to execute the stored processor-executable instructions to further perform an operation of: selecting the preset number of features from the feature set, wherein a total contribution rate of the preset number of features conforms to a preset contribution rate.

14. The chip grading system of claim 13, wherein ranking the chips in each group according to the scores of the chips in the group with respect to each of the preset number of features in the feature set comprises:
obtaining a level interval of each of the preset number of features in the feature set of each group according to the scores of the chips in the group with respect to each of the preset number of features in the feature set; and
ranking the chips in each group according to the level interval of each of the preset number of features in the feature set and the scores of the chips with respect to each of the preset number of features in the feature set.

15. The chip grading system of claim 14, wherein the ranking the chips in each group according to the level interval of each of the preset number of features in the feature set and the scores of the chips with respect to each of the preset number of features in the feature set comprises:
determining the level interval of each of the preset number of features in the feature set to which the chips belong according to the level interval of each of the preset number of features in the feature set and the scores of the chips with respect to each of the preset number of features in the feature set;
determining a sub-level of each of the preset number of features in the feature set to which the chips belong according to the level interval of each of the preset number of features in the feature set to which the chips belong; and
ranking the chips in each group according to the sub-level of each of the preset number of features in the feature set to which the chips belong.

16. The chip grading system of claim 15, wherein the ranking the chips in each group according to the sub-level of each of the preset number of features in the feature set to which the chips belong comprises:
for each of the chips in each group, calculating a total score of each of the chips with respect to each of the preset number of features in the feature set according to a weight of the sub-level of each of the preset number of features in the feature set to which the chips belong; and
determining the level to which each chip belongs according to the total score.

17. A chip packaging system, comprising a chip grading system of claim 12, wherein the processor is configured to execute the stored processor-executable instructions to further perform an operation of:
selecting, according to the grading results of the chips, at least two chips belonging to a same group and a same level for packaging.

18. A chip packaging system, comprising a chip grading system of claim 12, wherein the processor is configured to execute the stored processor-executable instructions to further perform operations of:
obtaining a group distribution and a level distribution of the chips on each wafer according to the grading results of the chips; and
selecting at least two wafers for packaging, wherein the chips on each of the at least two wafers have the group distribution and the level distribution satisfy a preset condition.

19. A non-transitory computer-readable storage medium having stored thereon computer-executable instructions that, when executed by a processor, cause the processor to perform operations of:
acquiring electrical performance test data of at least one wafer;
grouping chips on the wafer by using a clustering analysis algorithm according to the electrical performance test data of the wafer, so as to obtain a group to which each of the chips belongs, and establishing a clustering model;
for each group, extracting a feature set of each group by using a Principal Component Analysis (PCA) algorithm, and establishing a PCA model;
ranking chips in each group according to scores of the chips in the group with respect to each of a preset number of features in the feature set, so as to obtain a level to which each of the chips belongs; and
obtaining grading results of the chips according to both the group and the level to which each chip belongs.

20. The non-transitory computer-readable storage medium of claim 19, wherein extracting the feature set of each group by using the PCA algorithm and establishing the PCA model comprises:
for each group, extracting all features of the group by using the PCA algorithm to form the feature set, and establish the PCA model; and
the processor is configured to execute the stored processor-executable instructions to further perform an operation of: selecting the preset number of features from the feature set, wherein a total contribution rate of the preset number of features conforms to a preset contribution rate.
